(19) United States
(12) Patent Application Publication
(10) Pub. No.: US 2025/0391690 A1
(43) Pub. Date: Dec. 25, 2025

(54) BRUSH BOX WAFER NOTCH DETECTION METHODS AND EXTENDED FUNCTIONALITY

(71) Applicant: Applied Materials, Inc., Santa Clara, CA (US)

(72) Inventors: Justin H. WONG, Pleasanton, CA (US); Tom C. CHEN, Santa Clara, CA (US); Aliya KASSAM PIRBHAI, Santa Clara, CA (US)

(21) Appl. No.: 18/752,287

(22) Filed: Jun. 24, 2024

(51) Int. Cl. H01L 21/68; H01L 21/67

(52) U.S. Cl. CPC H01L 21/681; H01L 21/67023; H01L 21/67259

(57) ABSTRACT

The present disclosure describes an apparatus for substrate cleaning according to one or more embodiments. The apparatus includes a first support roller configured to support and rotate a substrate in contact with the first support roller, and a detection assembly. The detection assembly includes a body, a channel disposed through the body with a major axis aligned with an outlet of the channel, a sensor disposed in the body, and an inlet in fluid communication with the outlet. The outlet is configured to direct a fluid toward a surface of the substrate positioned in contact with the first support roller. The sensor is configured to direct an optical signal along the major axis of the channel and out of the outlet toward the substrate positioned in contact with the first support roller.

### BACKGROUND

### Field

Embodiments of the present disclosure generally relate to electronic device manufacturing, and in particular, to chemical mechanical polishing (CMP) systems and methods used in a semiconductor device manufacturing process.

### Description of the Related Art

During chemical mechanical polishing (CMP) processing, scattered particles, such as Cu, Ta, W, TaN, or Ti, may accumulate on both the front surface and back surface of a substrate. To properly remove the scattered particles, most post-CMP cleaning processes include physical cleaning as one of cleaning steps. Typically, the physical cleaning methods largely consist of physically removing excess metals with scrubbing brushes.

Post-CMP scrubbing brushes (i.e., scrubbers) remove particles by directly contacting the brush with the substrate surface. Typical scrubber assemblies consist of one brush on either side of the substrate surface. The brushes are spaced apart when the substrate is received or removed from the scrubbing assembly. The brushes are brought into contact with the substrate during cleaning.

The substrate is typically supported on a roller of the scrubbing assembly. In some instances, the roller includes a groove for receiving the substrate. One challenge encountered by the scrubbing assemblies is that the orientation of a substrate during processing is influenced by multiple factors. As a result, the substrate can slip relative to the roller when the substrate is disposed in the groove.

There is, therefore, a need for a brush cleaning unit that can improve substrate orientation monitoring and determine slippage of the substrate relative to the roller.

### SUMMARY

The present disclosure describes an apparatus for substrate cleaning according to one or more embodiments. The apparatus includes a first support roller configured to support and rotate a substrate in contact with the first support roller, and a detection assembly. The detection assembly includes a body, a channel disposed through the body with a major axis aligned with an outlet of the channel, a sensor disposed in the body, and an inlet in fluid communication with the outlet. The outlet is configured to direct a fluid toward a surface of the substrate positioned in contact with the first support roller. The sensor is configured to direct an optical signal along the major axis of the channel and out of the outlet toward the substrate positioned in contact with the first support roller.

In one or more embodiments, a system for cleaning a substrate in semiconductor manufacturing is provided. The system includes a tank, a cylindrical roller disposed in the tank, the cylindrical roller having a first axis, and a first support roller having a second axis disposed in the tank, the first axis disposed about perpendicular to the second axis. The first support roller is configured to support and rotate a substrate in contact with the first support roller. The system also includes a detection assembly disposed in the tank. The detection assembly includes a body, a channel disposed through the body. The channel includes an outlet, and an inlet in fluid communication with the outlet through the channel, and a sensor disposed in the body and configured to direct an optical signal out of the outlet.

In one or more embodiments, a system for cleaning a substrate in semiconductor manufacturing is provided. The system includes a tank, a drain, a first support roller disposed in the tank and configured to support and rotate a substrate, a detection assembly disposed in the tank, and a controller. The drain is disposed in a wall or a floor of the tank. The detection assembly is disposed in the tank and includes a body; a channel disposed through the body and having an outlet; a sensor disposed in the body; and an inlet fluidly coupled to the outlet through the channel. The sensor is configured to direct an optical signal through the channel and out of the outlet. The controller is communicatively coupled to the detection assembly. The controller includes memory. The memory includes instructions that, when executed by one or more processors, cause one or more operations to be conducted. The one or more operations includes at least one of determining whether a substrate is present in the tank; determining an orientation of the substrate in the tank; and determining whether the drain is in a clogged state.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic top view of a chemical mechanical polishing (CMP) system, according to certain embodiments.

FIG. 2A is an isometric view of a contact cleaning unit which may be utilized in the CMP system of FIG. 1, according to certain embodiments.

FIG. 2B is a top view of a brush cleaner in FIG. 2A, according to one or more embodiments.

FIG. 2C is an isometric view of the brush cleaner of FIG. 2B, according to one or more embodiments.

FIG. 3A is an isometric view of the detection assembly, of FIG. 2C, according to one or more embodiments.

FIG. 3B is an isometric view of the detection assembly, of FIG. 2C, according to one or more embodiments.

FIG. 4A is an isometric view of the detection assembly, of FIG. 2C, according to one or more embodiments.

FIG. 4B is an isometric view of the detection assembly, of FIG. 2C, according to one or more embodiments.

FIG. 5 is a diagram for performing a method of monitoring a condition of the brush box assembly according to one or more embodiments.

FIG. 6 is a diagram for performing a method of monitoring a condition of the brush box assembly according to one or more embodiments.

FIG. 7 is a diagram for performing a method of monitoring a condition of the brush box assembly according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein generally relate to chemical mechanical polishing (CMP) systems, and in particular, to cleaning systems used with CMP systems and methods related thereto.

In one embodiment, a brush cleaning system for cleaning a substrate includes a tank and a detection assembly. The detection assembly uses a sensor to detect changes in intensity of a signal and a controller configured to determine, based on the detected changes, at least one of a presence of a substrate, a substrate radial orientation, whether a roller supporting a substrate is slipping relative to the substrate, or whether a tank drain is clogged.

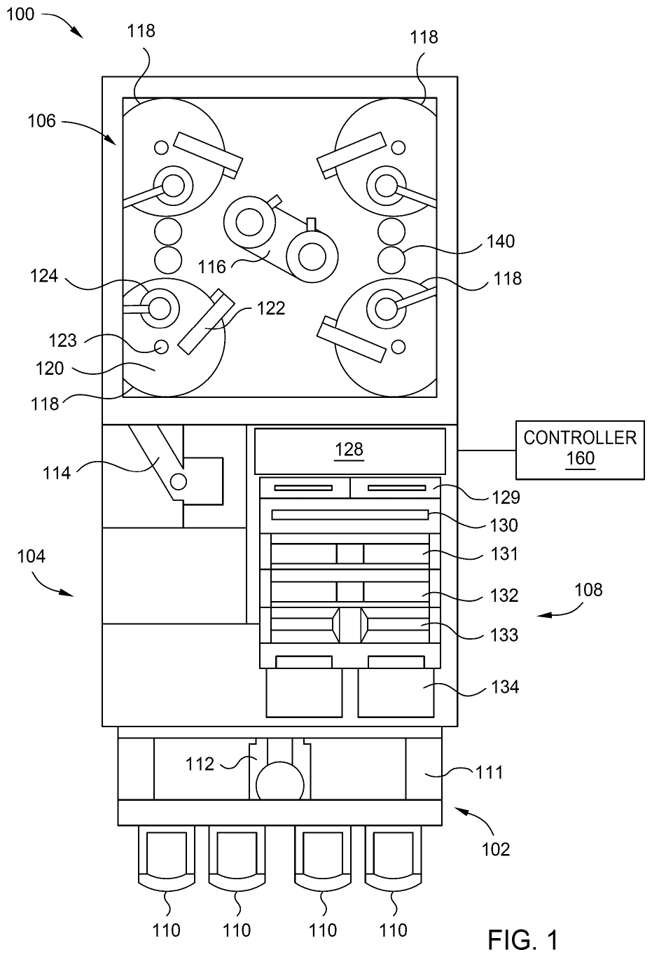

FIG. 1 illustrates a schematic top view of a chemical mechanical polishing (CMP) system 100. The CMP system 100 generally includes a factory interface module 102, an input module 104, a polishing module 106, and a cleaning module 108. These four major components are generally disposed within the CMP system 100.

The factory interface module 102 includes a support to hold a plurality of cassettes 110, a housing 111 that encloses a chamber, and one or more interface robots 112. The interface robot 112 generally provides the range of motion required to transfer substrates between the cassettes 110 and one or more of the other modules of the CMP system 100.

Unprocessed substrates are generally transferred from the cassettes 110 to the input module 104 by the interface robot 112. The input module 104 generally facilitates transfer of a substrate between the interface robot 112 and a transfer robot 114. The transfer robot 114 transfers the substrate between the input module 104 and the polishing module 106.

The polishing module 106 generally comprises a transfer station 116, one or more polishing stations 118, and one or more non-contact cleaning units 140. The transfer station 116 is disposed within the polishing module 106 and is configured to accept the substrate from the transfer robot 114. The transfer station 116 transfers the substrate to at least one carrier head 124 of a polishing station 118 that retains the substrate during polishing.

The polishing stations 118 each includes a rotatable disk-shaped platen on which a polishing pad 120 is situated. The platen is operable to rotate about an axis. The polishing pad 120 can be a two-layer polishing pad with an outer polishing layer and a softer backing layer. The polishing stations 118 each further includes a dispensing arm 122, to dispense a polishing liquid, e.g., an abrasive slurry, onto the polishing pad 120. In the abrasive slurry, the abrasive particles can be silicon oxide, but some polishing processes use cerium oxide abrasive particles. Each polishing station 118 can also include a conditioner head 123 to maintain the polishing pad 120 at a consistent surface roughness. In some embodiments, the conditioner head 123 is a dresser for a polishing pad.

The polishing stations 118 each includes at least one carrier head 124. The at least one carrier head 124 is operable to hold a substrate against the polishing pad 120 during a polishing operation. Following the polishing operation performed on a substrate, the at least one carrier head 124 transfers the substrate back to the transfer station 116.

The transfer robot 114 then removes the substrate from the polishing module 106 through an opening connecting the polishing module 106 with the remainder of the CMP system 100. The transfer robot 114 removes the substrate in a horizontal orientation from the polishing module 106 and transfers the substrate to the cleaning module 108.

The cleaning module 108 may employ methods like megasonic cleaning or spray cleaning to eliminate particles and contaminants from the substrate surface. For example, the cleaning module 108 may include megasonic cleaning, which utilizes high-frequency sound waves to create cavitation bubbles in the cleaning solution. The implosion of these bubbles generates shock waves that dislodge particles and contaminants from the substrate surface. Alternatively, the cleaning module 108 may include spray cleaning, where high-pressure jets of cleaning solution are used to dislodge particles and contaminants. The cleaning module 108 may be a single-arm spray cleaning module, employing a single spray arm moving back and forth across the substrate or a dual-arm spray cleaning module with two spray arms moving in opposite directions. Further, the non-contact cleaning unit 140 may be a rotating spray cleaning module that features a rotating spray head above the substrate, spraying cleaning solution from all angles. Additionally, the cleaning module 108 may be an inline spray cleaning module integrated into the CMP process line, transporting the substrate on a conveyor belt and spraying it from multiple angles. Conversely, an off-line spray cleaning module operates independently, cleaning substrates outside the CMP process line, which may be loaded manually or with the transfer robot 114.

The cleaning module 108 generally includes one or more cleaning devices that can operate independently or in concert. For example, the cleaning module 108 can include, from top to bottom in FIG. 1, a sulfuric peroxide mixture (SPM) module 128, an input module 129, one or more brush or buffing pad module 131, 132, a megasonic cleaner 133, and a drying module 134. Other possible cleaning devices include chemical spin cleaners and jet spray cleaners (not shown). A transport system, e.g., an overhead conveyor 130 that supports robot arms, can walk or run the substrate from cleaning device to cleaning device. The substrate is then transferred to the megasonic cleaner 133 in which high frequency vibrations produce controlled cavitation in a cleaning liquid to clean the substrate. Alternatively, the megasonic cleaner 133 can be positioned before the brush or buffing pad module 131, 132. A final rinse can be performed in a rinsing module before being transferred to the drying module 134.

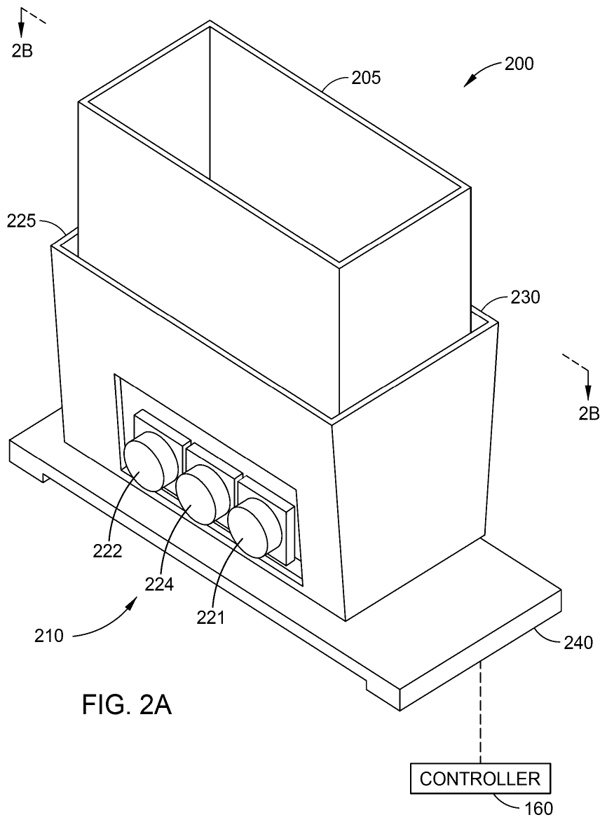

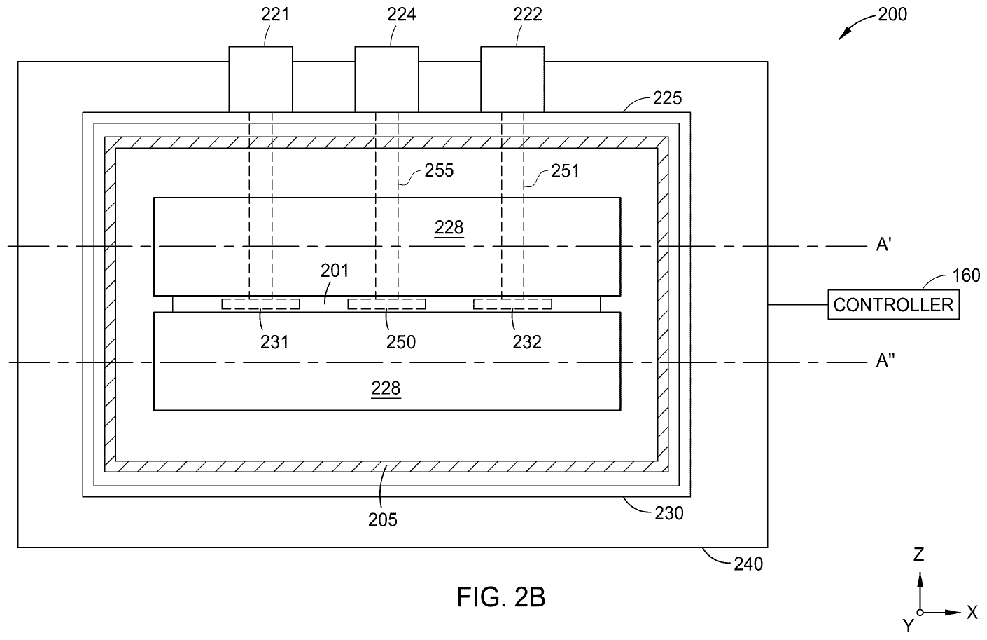

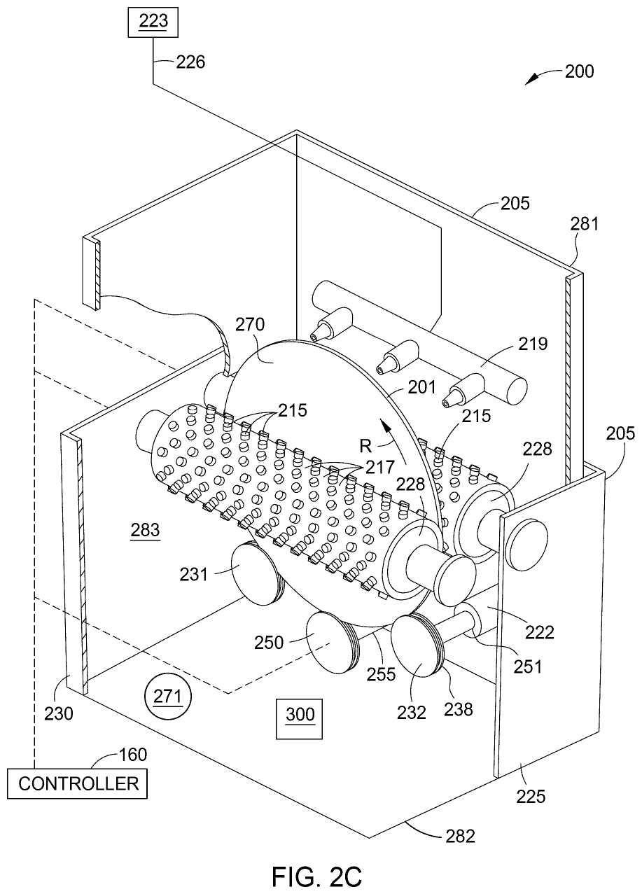

The one or more brush or buffing pad module 131, 132, as described further below regarding FIGS. 2A-2C, directly contacts the substrate and may be a brush scrubbing module using a rotating brush to scrub the substrate surface. Briefly, the one or more brush or buffing pad module 131, 132 is a device in which the substrate can be placed and the surfaces of the substrate are contacted with rotating brushes or spinning buffing pads to remove any remaining particulates. In some embodiments, a brush moves back and forth across the substrate, applying cleaning solution during the scrubbing process. The rotating brush uses friction between the brush bristles and the substrate surface, as well as centrifugal force generated by the rotating brush to dislodge particles and contaminants from the substrate surface. The cleaning solution concurrently dissolves and weakens the bonds between particles and the substrate surface. Following dislodgment of contaminants from the substrate surface, the cleaning solution, flowing through the brush bristles, flushes the contaminants from the substrate surface.

The CMP system 100 includes a controller 160, which generally includes one or more processors, memory, and support circuits. The one or more processors may include a central processing unit (CPU) and may be one of any form of a general purpose processor that can be used in an industrial setting. The controller 160 is communicatively coupled to the detection assembly 300. The memory includes instructions that, when executed by one or more processors cause one or more operations to be conducted, the one or more operations include at least one of determining whether a substrate is present in the tank, determining an orientation of the substrate in the tank and determining whether the drain is in a clogged state. The CPU can cause one or more operations to be conducted, the one or more operations comprise at least one of determine if a substrate is present in the tank, determining an orientation of the substrate, when present, within the tank, and determining if the tank's drain is in a clogged state. The operations are described below and at least in relation to methods 500, 600, and 700. The memory, or non-transitory computer-readable medium, is accessible by the one or more processors and may be one or more of memory such as random access memory (RAM), read only memory (ROM), floppy disk, hard disk, or any other form of digital storage, local or remote. The support circuits are coupled to the one or more processors and may comprise cache, clock circuits, input/output subsystems, power supplies, and the like. The various methods disclosed herein may generally be implemented under the control of the one or more processors by the one or more processors executing computer instruction code stored in the memory as, for example, a software routine. When the computer instruction code is executed by the one or more processors, the one or more processors controls the CMP system 100 to perform processes in accordance with the various methods disclosed herein.

FIG. 2A is an isometric view of a brush box assembly 200, which may be utilized as one or more brush or buffing pad modules 131, 132 in the CMP system 100 as described above. A lid portion of the brush box assembly 200, which includes a door, has been removed from FIGS. 2A-2C for ease of discussion. FIG. 2B is a top view of the brush box assembly 200 loaded with a substrate 201. FIG. 2C is an isometric view of the interior of the brush box assembly 200 showing the cylindrical rollers 228 in a processing position, in which cylindrical rollers 228 are closed (e.g., pressed) against major surfaces of the substrate 201. The brush box assembly 200 shown in FIGS. 2A-2C can be a scrubber type or brush box-type horizontal cleaner. The example brush box assembly 200 includes a tank 205 that is supported by a first support 225 and a second support 230. In one embodiment, the first support 225 and the second support 230 are movably coupled to a base 240. In some embodiments which may be combined with other embodiments, the tank 205 is formed by the first support 225 and the second support 230 such that the first support 225 and the second support 230 form sidewalls of the tank 205 and the base 240 is a floor of the tank. In one embodiment, the tank 205 includes the first support 225, the second support 230, and the base 240. The tank 205 includes an upper ledge 281, a floor 282, a drain 271, and encloses a tank volume 283. The drain 271 is disposed in the floor 282 of the tank 205 through the base 240. The drain 271 is configured to remove fluid from the tank 205. The drain 271 is disposed proximate or in the floor of the tank 205. In some embodiments which may be combined with other embodiments, the drain 271 is disposed in a wall or a floor of the tank 205. In some embodiments, the brush box assembly 200 includes a fume exhaust (not shown) through a wall such that the drain 271 removes liquids and the fume exhaust removes gases during operation.

The brush box assembly 200 includes a plurality of scrubbing devices, such as at least first and second cylindrical rollers 228, located inside the tank 205. In this example, a first cylindrical roller 228 is mounted to the first support 225, and a second cylindrical roller 228 is mounted to the second support 230. The first and second cylindrical rollers 228 may be coupled to actuators (not shown) for rotating the cylindrical rollers 228 about axes A′ and A″. The cylindrical rollers 228 are coupled to and controlled by the controller 160, which may control the rotational speed or rotational direction of the rollers 228. In one example, the first roller 228 is rotated in a clockwise direction, and the second roller 228 is rotated in a counterclockwise direction.

In operation, the first and second supports 225, 230 may be moved simultaneously relative to a base 240. Such movement may cause the first and second cylindrical rollers 228 to close against the substrate 201 as shown in FIG. 2C, or to cause the first and second cylindrical rollers 228 to be spaced apart to allow insertion and/or removal of the substrate 201 from the brush box assembly 200. In some embodiments, each cylindrical roller 228 includes a plurality of raised nodules 215 across its outer surface and a plurality of valleys 217 located among the nodules 215.

The brush box assembly 200 also includes a substrate support system 210 adapted to support and rotate a substrate 201. In one embodiment, the substrate support system 210 includes one or more support rollers 231, 232 rotatable by one or more rotation actuators, such as drive motors 221, 222. The substrate support system 210 also includes an idler module 224. In some embodiments, the idler module 224 is a rotational measuring module that detects the angular displacement and rotational speed of the substrate 201 through an idler roller 250. In some embodiments, the idler module 224 is an optical measurement module. In some embodiments, the idler module 224 includes a stepper motor. As shown in FIGS. 2B and 2C, each support roller 231, 232 is disposed at the end of an output shaft 251 of a respective drive motor 221, 222. The support rollers 231, 232 are configured to support, are positioned in contact with, and facilitate rotation of the substrate 201 about an axis that is perpendicular to the horizontal plane (i.e., X-Y plane). In one example, each of the support rollers 231, 232 include a groove 238 adapted to vertically support the substrate 201. Rotation of the support rollers 231, 232 causes rotation of the substrate 201. In some embodiments, the rollers 231, 232 are made from a plastic material or other polymeric material. In some embodiments which may be combined with other embodiments, the rollers 231, 232 are consumables that are replaced after a certain period. For example, when the rollers 231, 232 no longer sufficiently hold the substrate 201 such that the substrate 201 slips and does not rotate while the roller does rotate.

The substrate support system 210 also includes the idler roller 250 for use with the brush box assembly 200. The idler roller 250 is configured to selectively grip the substrate 201. The idler roller 250 is coupled to and rotatable with a rotating shaft 255 coupled to the idler module 224. In this example, the idler roller 250 is coupled to a distal end of the rotating shaft 255, and the proximal end of the rotating shaft 255 is rotatably coupled to the tank 205. In some embodiments which may be combined with other embodiments, the idler roller 250 is coupled to the controller 160 and measures the number of rotations the substrate 201 has made during an operation. The controller 160 is able to use the number of rotations, the radial orientation, and/or the angular rotation to determine the orientation of the substrate 201.

As shown in FIGS. 2A-2C, the pair of cylindrical rollers 228 are supported by a pivotal mounting adapted to move the cylindrical rollers 228 into and out of contact with the substrate 201, such as a semiconductor wafer. During processing in the brush box assembly 200, the cylindrical rollers 228 are brought into contact with the substrate 201 while the cylindrical rollers 228 are rotated by the actuators (not shown). At the same time, the substrate 201 is rotated in the R direction by rotating the support rollers 231, 232, and the substrate 201 is gripped by the idler roller 250, as shown in FIG. 2C. A cleaning fluid, such as deionized water and/or acid or base containing aqueous solution, is applied to the surface of the substrate 201 from a fluid source while the substrate 201 and cylindrical rollers 228 are rotated by the various actuators and motors.

The brush box assembly 200 may further comprise a plurality of sprayers 219 coupled to a source 223 of cleaning fluid via a supply pipe 226. The sprayers 219 are configured to dispense a high-pressure liquid spray onto the substrate surfaces, aiding in the removal of particles, contaminants, and residues. The sprayers 219 can incorporate various configurations, such as a fluid jet, spray bar with nozzles, shower-style spray manifold, or cryogenic aerosol jet.

In various embodiments of the present disclosure, the cleaning fluid supplied from the source 223 utilized in the brush cleaner may include, but is not limited to deionized (DI) water, diluted citric acid, diluted Quaternary ammonium compound (a mixture of organic solvents, such as glycol ether, tetramethyl ammonium hydroxide, and other additives), diluted ammonium hydroxide (NH₄OH), diluted hydrogen peroxide (H₂O₂), NH₄OH and H₂O₂ mixture (SC1), diluted hydrofluoric acid, sulfuric acid (H2SO4) and hydrogen peroxide (H₂O₂) mixture (SPM), Electra clean, or any other liquid solution used for substrate cleaning.

In one or more embodiments, the sprayers 219 may be positioned to spray a cleaning fluid at the surfaces of the substrate 201 or at the one or more cylindrical rollers 228 during a scrubbing process. In one or more embodiments, substrate cleaning fluid and/or brush cleaning fluid may be supplied from an internal region of the cylindrical rollers 228. Fluids provided to the interior of the cylindrical rollers 228 may clean the surface of the substrate 201 or remove debris found on the surface of the rollers 228.

As shown in FIG. 2C, the brush box assembly includes a detection assembly 300. The detection assembly 300 is directed toward a major surface 270 of the substrate 201. In some embodiments that may be combined with other embodiments, the detection assembly 300 is disposed closer to the floor 282 than the upper ledge 281 and can be used to detect issues with the brush box assembly 200. In some embodiments that may be combined with other embodiments, the detection assembly 300 is disposed nearer the upper ledge 281 to enhance accuracy. The detection assembly 300 is described below.

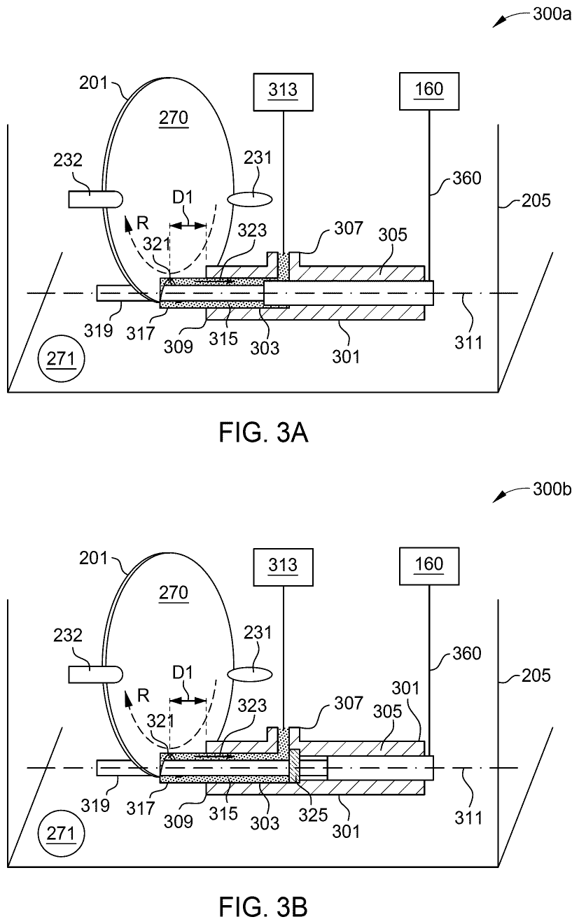

FIG. 3A is an isometric view of one embodiment of the detection assembly 300, of FIG. 2C, according to one or more embodiments.

As illustrated in FIG. 3A, the detection assembly 300a is part of an apparatus for substrate cleaning. The detection assembly 300a includes a body 301, a channel 303 disposed through the body 301, a sensor 305, a channel inlet 307, and a channel outlet 309.

The channel 303 includes a major axis 311 aligned with the channel outlet 309. The channel outlet 309 is configured to direct a fluid toward the major surface 270 of the substrate 201. The channel inlet 307 is in fluid communication with and fluidly coupled to the channel outlet 309 via the channel 303. In some embodiments that may be combined with other embodiments, a fluid 315 from a liquid supply 313 is supplied to the channel inlet 307, flows past the sensor 305 and out of the channel outlet 309. The fluid travels a distance D1 between the channel outlet 309 and the major surface 270 of the substrate 201. In some embodiments which may be combined with other embodiments, the distance D1 is about 1 millimeters to about 20 millimeters, for example less than about 15 millimeters, for example about 10 millimeters. The fluid 315 leaving the outlet 309 forms a liquid column 317 between the channel outlet 309 and the major surface 270 of the substrate 201. In some embodiments which may be combined with other embodiments, the outlet 309 is disposed less than 10 millimeters from the substrate 201 when the substrate 201 is disposed in contact with the rollers 231, 232. In some embodiments which may be combined with other embodiments, the fluid 315 is a transparent liquid, for example water, reverse osmosis (RO) deionized (DI) water, but other liquids are contemplated, for example, a cleaning fluid could also be supplied.

The sensor 305 is disposed in the body 301. The sensor 305 is configured to direct an optical signal 319 along the major axis 311 of the channel 303 and out of the outlet 309 toward the substrate 201. In some embodiments which may be combined with other embodiments, the sensor 305 is an optical sensor communicatively coupled to the controller 160. For example, the sensor 305 includes a fiber optic cable configured to direct the optical signal 319 through the fluid 315 and through the liquid column 317 between the outlet 309 and the major surface 270 of the substrate 201. The optical signal 319 either passes through a notch 321 in the substrate 201 or reflects off the major surface 270 of the substrate in the form of a reflected signal 323. The notch 321 is disposed at the radially outward edge of the substrate 201. The sensor 305 detects the reflected signal 323, as described in more detail below. In some embodiments which may be combined with other embodiments, the sensor 305 is coupled to the controller 160 by a fiber optic cable 360 for transmitting optical signals. The fiber optic cable 360 is configured to send and receive optical signals between the sensor 305 and the controller 160.

FIG. 3B is an isometric view of another embodiment of the detection assembly 300, of FIG. 2C, according to one or more embodiments.

As illustrated in FIG. 3B, the detection assembly 300b is similar to the detection assembly 300a. In some embodiments which may be combined with other embodiments, the detection assembly 300b further includes a window 325. The window 325 is disposed between the sensor 305 and the portion of the channel 303 between the channel inlet 307 and the channel outlet 309. As fluid 315 passes through the channel 303, the window 325 allows the optical signal 319 to pass through the window 325 and into the channel 303 and into the liquid column 317. The window 325 also allows the sensor 305 to be separated from the fluid 315 flowing through the channel 303. In some embodiments which may be combined with other embodiments, the window 325 is a transparent material, for example the window 325 is glass, sapphire, a transparent ceramic, or a transparent polymer, but other materials are contemplated. For example the window 325 is quartz. In some embodiments which may be combined with other embodiments, the window 325 is an optical filter configured to filter light wavelengths from the optical signal 319 and/or the reflected signal 323. Using the liquid column 317 reduces the potential interference from droplets produced during operation. For example, by using a liquid column 317, water droplets are not formed between the major surface 270 of the substrate 201 and the optical signal 319, which would otherwise disperse or reduce the quality of the reflected signal 323. In addition, the fluid 315 may help to reduce any photonic reaction that may occur on the substrate 201.

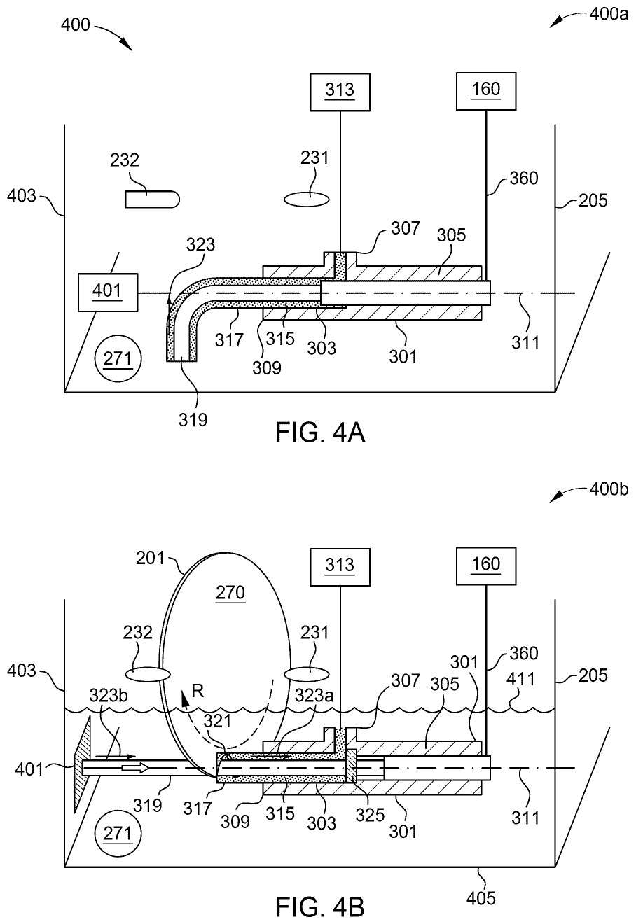

FIG. 4A is an isometric view of the detection assembly 400 according to one or more embodiments. The detection assembly 400 is similar to the detection assembly 300, 300a, or 300b in FIGS. 2C, 3A, and 3B.

As illustrated in FIG. 4A, when the substrate is not disposed in the tank 205, the liquid column 317 curves downwardly, and the optical signal 319 diffracts and disperses such that the optical signal 319 is not reflected back towards the sensor 305. When the sensor 305 does not detect the reflected signal 323 after rotating the substrate 201, the controller 160 creates an alert that a substrate is not present in the tank 205. By rotating the substrate 201 before creating the alert, the controller 160 is able to verify the sensor 305 is not aligned with the notch 321 and provide a false alert. In this state, the controller 160 will also be able to form an alert that the drain 271 is functioning properly (i.e., fluid is properly draining from the tank 205).

The detection assembly 400 also includes a target 401. The target 401 is disposed in the tank 205. In some embodiments which may be combined with other embodiments, the target 401 is disposed on a sidewall 403 of the tank 205. In some embodiments which may be combined with other embodiments, the target 401 is a body disposed on a floor 405 of the tank 205 with a reflective surface aligned with the major axis 311. The reflective surface of the target 401 can be the target 401 itself of a surface of the target 401. The target 401 includes a material that, when receiving the optical signal 319, does/forms a second reflected signal 323b (FIG. 4B). The material of the target 401 or the reflective surface includes mirrors, dark materials, or other materials similar to the substrate 201 that will form the second reflected signal 323b at a similar intensity to the reflected signal 323 from the substrate 201. This is described in more detail below. A drain 271 that is not functioning properly is in a clogged state, i.e., the drain 271 is clogged and fluid is not properly draining from the tank 205. The target 401 is configured to reflect a signal that is detected by the sensor 305 when the drain 271 is in a clogged state. The clogged state detection is described below with respect to FIG. 4B. When the drain 271 is in an unclogged state, the optical signal 319 translation is restricted to within the liquid column 317. For example, since the liquid column 317 does not extend to the target 401, the optical signal 319 diffracts and disperses against the liquid column 317 where the liquid column 317 curves away from the major axis 311. As such, the optical signal 319 does not reach the target 401, and thus, is not reflected back to the sensor 305.

FIG. 4B is an isometric view of the detection assembly 400 according to one or more embodiments when the drain 271 is in the clogged state (i.e, fluid 411 is not properly draining from the tank 205).

As illustrated in FIG. 4B, the target 401 includes a reflective surface configured to reflect the optical signal 319 from the sensor 305. In some embodiments which may be combined with other embodiments, when the drain 271 is in a clogged state, the level of the fluid 411 in the tank 205 rises above the height of the axis 311. Once the level of the fluid 411 in the tank 205 is above the height of the axis 311, the optical signal 319 is able to be reflected from the target 401 to form the second reflected signal 323b, which is detected by the sensor 305. The optical signal 319 is able to translate along the major axis 311 to the target 401 due to the presence of the fluid 411 between the sensor 305 and the target 401. That is, the optical signal 319 is unrestricted by the fluid 411 instead of being confined by the liquid column 317.

When the substrate 201 is present the optical signal 319 is directed to and reflects off the substrate 201 to form a first reflected signal 323a having a first intensity that is detected by the sensor 305. As the substrate 201 is rotated by the support rollers 231, 232 and the notch 321 is disposed along the major axis 311, the optical signal 319 translates through the notch 321. As the optical signal 319 translates through the notch 321, a second reflected signal 323b is produced when the target 401 forms the second reflected signal 323b from the optical signal 319. The second reflected signal 323b has a second intensity similar to the first intensity of the first reflected signal 323a. The sensor 305 is able to detect both of the first reflected signal 323a and the second reflected signal 323b and the controller 160 creates an alert that the drain 271 is in a clogged state because the controller 160 never detected a lack of a signal associated with the liquid column 317 passing through the notch 321. For example, when the sensor 305 detects a second intensity of 60% or less than the first intensity, the liquid column 317 is passing through the notch 321 and the sensor 305 detects the reduction. In contrast, when the second intensity is greater than 60% of the first intensity, the sensor 305 is detecting the second reflected signal 323b from the target 401 because the drain 271 is in a clogged state. The controller 160 includes a preset threshold such that the sensor 305 detects an intensity at a lower limit relative to the intensity when light is reflected from the substrate. In the above example, the lower limit was 60% but other limits are contemplated. For example, the sensor detects an 80% intensity when light is not reflected from the substrate 201 or the target 401 and 100% intensity when light is reflected from the substrate 201 or the target 401. In yet another example, the sensor detects a 70% intensity when light is not reflected from the substrate 201 or the target 401 and 100% intensity when light is reflected from the substrate 201 or the target 401. If the controller 160 determines the intensity has not dropped below the lower limit, the controller 160 creates an error alert corresponding to a clogged state.

In contrast, when the drain 271 is in an unclogged state, the liquid column 317 collapses before it can reach the target 401. Thereby, the optical signal 319 is dispersed before it can reach the target 401 and the sensor 305 detects the periodic changes in detected light intensity.

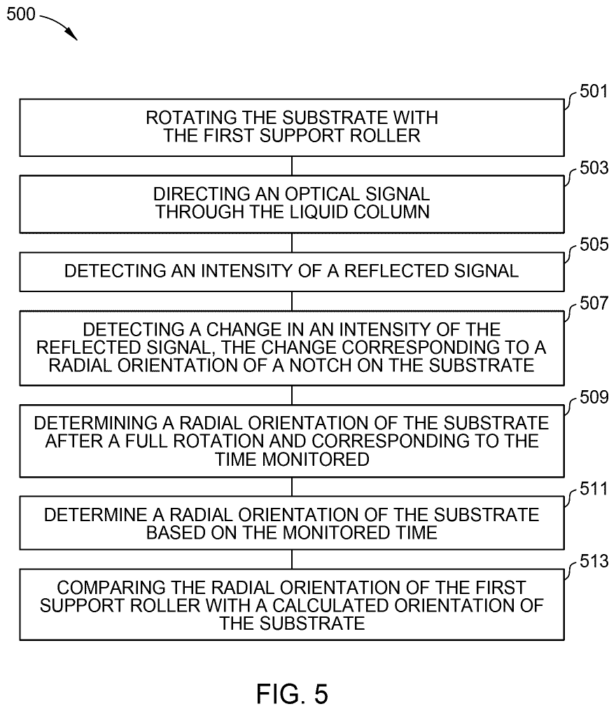

FIG. 5 is a diagram for performing a method 500 of monitoring a condition of the brush box assembly 200 according to one or more embodiments. The method 500 is described in relation to FIGS. 3A and 3B and can be used to detect an orientation of the substrate 201.

At operation 501, the liquid supply 313 provides the fluid 315 to the channel inlet 307. The fluid 315 flows through the channel 303, and out of the channel outlet 309 to form the liquid column 317. The liquid supply 313 provides the fluid 315 to flow at a flow rate of about 0.1 liters per minute to about 10 liters per minute. The liquid column 317 is formed by a laminar flow of the fluid 315. The liquid column 317 is between the substrate 201 positioned on the first and second support rollers 231, 232 within the brush box 200. The liquid column 317 has a length D1 so that the liquid column 317 is about parallel with the major axis 311 at the length D1.

At operation 501, the substrate 201 is also rotated by one or both of the first support roller 231 and the second support roller 232 and the drive motors 221, 222. In some embodiments which may be combined with other embodiments, the substrate 201 may also be rotated by the idler roller 250 and the idler module 224 of FIG. 2B. In some embodiments which may be combined with other embodiments, at least one of the drive motors 221, 222 and the idler module 224 is a stepper motor configured to communicate with the controller 160. The controller 160 monitors at least one of the motors/modules 221, 222, 224 to determine at least one of the number of rotations of the rollers 231, 232, 250 and their radial orientation, which corresponds to the radial orientation of the substrate 201 coupled to the rollers 231, 232, 250. For example, when the first motor 221 is a stepper motor providing the radial orientation of the first support roller 231 to the controller 160, the controller 160 uses the radial orientation of the first support roller 231 to determine the corresponding radial orientation of the substrate 201 based on the diameter of the first support roller 231 and the diameter of the substrate 201.

In some embodiments which may be combined with other embodiments, the controller 160 uses a period of time the rollers 231, 232, 250 have been rotating to determine the calculated radial orientation of the substrate 201. For example, the controller 160 determines the amount of time the idler roller 250 has been rotated by the substrate 201 to determine radial orientation of the substrate 201 based on the diameter of the idler roller 250 and the diameter of the substrate 201. In this non-limiting example, at least one of the first support roller 231 and the second support roller 232 drives the rotation of the substrate 201 while the idler roller 250 only sends feedback to the controller 160. In some embodiments which may be combined with other embodiments, the idler roller 250 drives the rotation of the substrate 201 while at least one of the first support roller 231 and the second support roller 232 send feedback to the controller 160.

In some embodiments which may be combined with other embodiments, the controller 160 uses one or more of the radial orientation of one or more of the rollers 231, 232, 250 based on the feedback from the motors/modules 221, 222, 224 and the period of time one or more of the motors/modules 221, 222, 224 has been rotating to determine the calculated radial orientation of the substrate 201.

At operation 503, the sensor 305 directs the optical signal 319 through the liquid column 317. The optical signal 319 translates toward the substrate 201 through the liquid column 317. When the optical signal 319 interacts with the major surface 270 of the substrate 201, the reflected light forms the reflected signal 323.

At operation 505, the sensor 305 detects an intensity of the reflected signal 323. This intensity of the reflected signal 323 may be a non-zero value corresponding to the substrate 201 or a an intensity less than 60% of the intensity of the reflected signal 323 corresponding to the notch.

At operation 507, the sensor 305 detects a change in the intensity of the reflected signal 323. The change in the intensity of the reflected signal 323 corresponds to a radial orientation of the notch 321 of the substrate 201. Once the controller 160 determines there has been a change in the intensity of the reflected signal 323, the controller 160 determines the radial orientation of the substrate 201.

When the substrate 201 is rotated such that the notch 321 is aligned with the major axis 311, the optical signal 319 is dispersed as the liquid column 317 extends past the substrate 201 at a length greater than D1 and as the liquid column 317 curves away from the major axis 311. The reflected signal 323 is now directed away from the sensor 305 so the sensor 305 detects a change in intensity. For example, the change in intensity is a reduction of signal intensity as the detected signal intensity is less than 60% of the reflected signal 323. This change in intensity corresponds to the notch 321 being present in the optical signal 319 path rather than the major surface 270 of the substrate 201. The intensity of the reflected signal 323 is transmitted to the controller 160 to determine the change in intensity as the notch 321 is aligned with the optical signal 319. The controller 160 may then determine the radial orientation of the substrate 201.

At operation 509, the controller 160 monitors a time between a first change in intensity and a second change in intensity of the reflected signal 323. For example, the controller 160 measures and uses the time between the first reduction of intensity to 0 and a second reduction of intensity to 0 to determine the rotations per minute (RPM) of the substrate 201.

At operation 511, the controller 160 determines the radial orientation of the substrate 201 after a full rotation and corresponding to the time monitored. For example the controller 160 determines the radial orientation of the substrate 201 based on monitored time it took to make a full rotation. The controller 160 determines the amount of time it took to rotate the substrate 201.

At operation 513, the radial orientation of the substrate 201 is compared to a calculated orientation of the substrate 201. The controller 160 determines the calculated orientation of the substrate 201 using the radial orientation of at least one of the rollers 231, 232, 250. For example, the controller 160 determines the calculated orientation of the substrate 201 using the radial orientation of the first support roller 231.

When the controller 160 determines a difference in radial orientation of the substrate 201 and calculated orientation of the substrate 201, the controller 160 creates an alert that at least one of the rollers 231, 232, 250 needs maintenance. For example, the rollers 231, 232, 250 maintenance may be replacing a roller as the environment of the system has degraded the roller such that it slips against the substrate 201 during rotation.

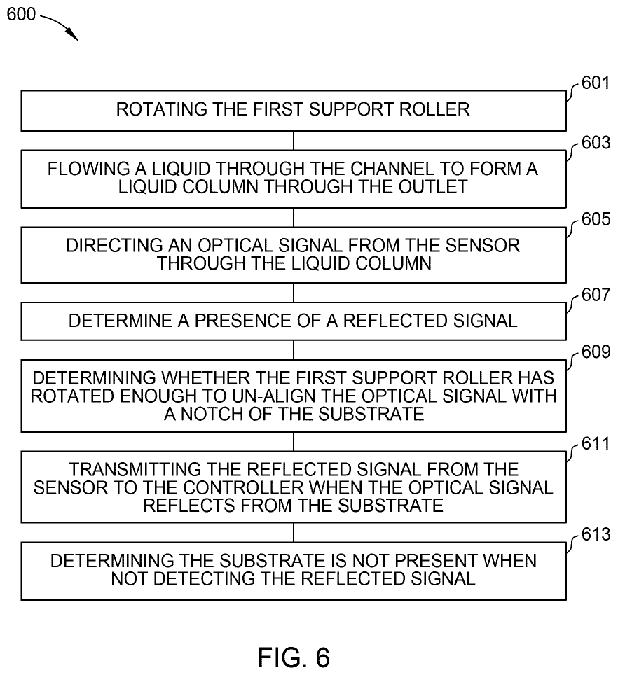

FIG. 6 is a diagram for performing a method 600 of monitoring a condition of the brush box assembly according to one or more embodiments. The method 600 is described in relation to FIGS. 3A, 3B, and 4A. The method can be used to detect a presence of the substrate 201 in the tank 205.

At operation 601, the controller 160 sends instruction to at least one of the motors/modules 221, 222, 224 that causes at least one of the rollers 231, 232, 250 to begin rotation. For example, the controller 160 sends instruction to rotate the first support roller 231.

At operation 603, the fluid 315 flows out of the outlet 309 to form the liquid column 317.

At operation 605, the fluid 315 flows out of the outlet 309 and the sensor 305 directs the optical signal 319 through the liquid column 317.

At operation 607, while at least one of the rollers 231, 232, 250 is rotating, the controller 160 determines if the sensor 305 has detected the reflected signal 323.

The controller 160 determines if the sensor 305 should have detected the reflected signal 323. For example, if the substrate 201 should be in the tank 205, the controller 160 determines if the sensor 305 has detected an intensity of the reflected signal 323.

At operation 609, the controller 160 determines if at least one of the rollers 231, 232, 250 has rotated the substrate 201 to un-align the optical signal 319 (the major axis 311) with the notch 321 of the substrate 201. For example, the controller 160 determines if the first support roller 231 has rotated the substrate 201 to un-align the optical signal 319 (the major axis 311) with the notch 321 of the substrate 201. In some embodiments which may be combined with other embodiments, the substrate 201 only need be rotated about 1° to rotate the notch 321 past the optical signal 319.

The substrate 201 is rotated enough to verify the major axis 311 was not aligned with the notch 321 of the substrate 201 while determining the presence of the reflected signal 323.

At operation 611, the sensor 305 transmits the reflected signal 323 to the controller 160 when the optical signal 319 reflects from the substrate 201 back through the liquid column 317. For example, when the optical signal 319 passes through the notch, then after the substrate 201 is rotated, the optical signal 319 reflects from the substrate 201 to form the subsequently detected reflected signal 323. In some embodiments which may be combined with other embodiments, the optical signal 319 the optical signal 319 reflects from the substrate 201 to form the detected reflected signal 323. The substrate 201 is then rotated to align the notch 321 with the optical signal 319 and the sensor no longer detects the reflected signal 323 until substrate 201 is further rotated to form the detected reflected signal 323, which is sent to the controller 160.

At operation 613, the controller 160 determines the substrate 201 is not present when the reflected signal 323 is not detected during operation 607, operation 611, or operation 613. If the reflected signal 323 has not been detected, even after the first support roller 231 would have sufficiently rotated a substrate, the controller 160 generates an alert. In some embodiments which may be combined with other embodiments, the alert indicates that a substrate 201 is not present in the tank 205.

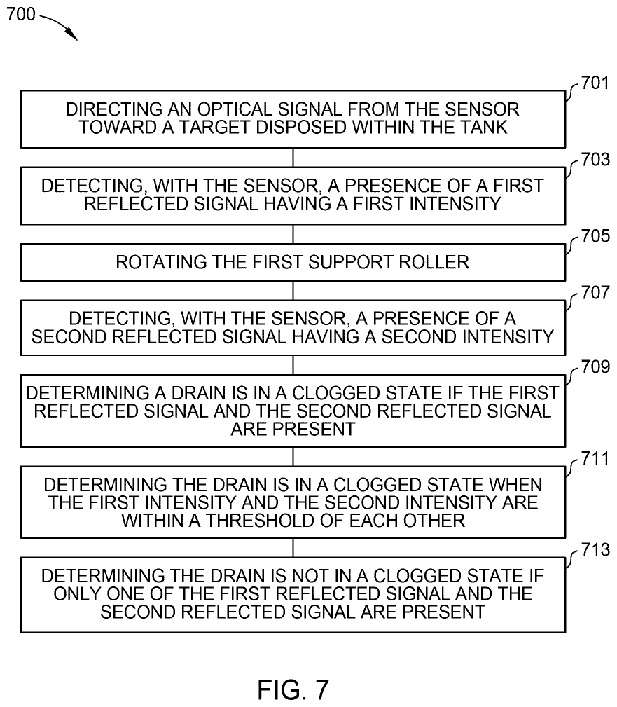

FIG. 7 is a diagram for performing a method 700 of monitoring a condition of the brush box assembly 200 according to one or more embodiments. The method 700 is described in relation to FIGS. 3A, 3B, and 4B and can be used to detect if the drain 271 is in a clogged state.

At operation 701, the sensor 305 directs the optical signal 319 toward the target 401. The optical signal 319 travels through the liquid column 317 toward the target 401 and the substrate 201.

At operation 703, the sensor 305 detects a presence of at least one of a first reflected signal 323a having a first intensity or a second reflected signal 323b having a second intensity. The controller 160 determines and stores the intensity of the respective first reflected signal 323a or the second reflected signal 323b.

At operation 705, the controller 160 sends instruction to at least one of the motors/modules 221, 222, 224 that causes at least one of the rollers 231, 232, 250 to begin rotation.

At operation 707, after at least one of the rollers 231, 232, 250 has rotated the substrate 201, the sensor 305 detects an intensity that has fluctuated in and out of a threshold range. The controller 160 determines and stores the intensity of the respective first reflected signal 323a or the second reflected signal 323b.

At operation 709, if the controller 160 determines the first reflected signal 323a and the second reflected signal 323b are present, the controller 160 determines the drain 271 is in a clogged state. The controller 160 determines the first reflected signal 323a and the second reflected signal 323b are present because the sensor 305 detects an intensity that has stayed within a threshold range. For example, the sensor 305 would detect a reduction in intensity. The threshold range is an established range of optical intensity measured by the sensor 305. The sensor 305 converts the measured intensity into an electrical signal to be read by the controller 160. For example, the sensor 305 converts the optical intensity to a voltage between 0 v and 5 v, in another example the sensor 305 converts the optical intensity to a voltage between 0 v and 10 v. The changes in intensity are correlated to the electrical signal read by the controller 160.

For example, the controller 160 establishes a first intensity based on the electrical signal from the sensor 305. The controller 160 uses the first intensity to establish a threshold. The threshold may be +/−20% of the first intensity or the corresponding electrical signal read by the controller 160. For example if the controller 160 receives an 8 v signal corresponding to a first intensity the threshold would be about 6.4 v to 9.6 v. The controller 160 determines if the electrical signal from the sensor 305 changes enough to be outside of the threshold which corresponds to the notch 321. If the electrical signal from the sensor 305 stays within the threshold then light has been able to reflect from the target 401 and keep the measured intensity within the threshold.

At operation 711, if the controller 160 determines the intensity of first reflected signal 323a and the intensity of the second reflected signal 323b keep the intensity of light within the threshold, the controller 160 determines the drain 271 is in a clogged state. For example, if while rotating the substrate 201, the sensor 305 detects a similar second intensity and the first intensity, the controller 160 is unable to determine when the notch 321 is aligned with the major axis 311. If the intensity of the respective reflected signals 323a, 323b is within a threshold such that the intensity of the signal detected by the sensor 305 drops by 20% or more, the controller 160 determines that the optical signal 319 is translating through the liquid column 317 to the substrate 201 and also, when the notch 321 is aligned with the major axis 311, the optical signal 319 translates to the target 401 through the fluid 411, as illustrated in FIG. 4B. For example, the optical signal 319 is only able to reflect off the target 401 when the tank 205 has enough fluid for the optical signal 319 to be un-restricted by the liquid column 317.

At operation 713, if the controller 160 determines that only one of the first reflected signal 323a or the second reflected signal 323b is present, the controller 160 determines the drain 271 is not in a clogged state.

The above described subject matter allows for enhanced system maintenance, accuracy, and reliability. By actively monitoring a substrate in system with both the radial orientation of the rollers to create a calculated orientation and comparing the calculated orientation with the orientation determined using an optical sensor, downtime and errors can be reduced while through-put is enhanced.

It is contemplated that one or more aspects disclosed herein may be combined. As an example, one or more aspects, features, components, operations and/or properties of the CMP system 100; the substrate support system 201; detection assembly 300, 300a, 300b, 400; the controller 160; and/or the methods 500, 600, 700 may be combined.

While the foregoing is directed to embodiments of the present disclosure, other and further embodiments of the disclosure may be devised without departing from the basic scope thereof, and the scope thereof is determined by the claims that follow.

What is claimed is:

1. An apparatus for substrate cleaning, the apparatus comprising:
a first support roller configured to support and rotate a substrate in contact with the first support roller; and
a detection assembly, the detection assembly comprising:
a body;
a channel disposed through the body, the channel having a major axis aligned with an outlet of the channel, the outlet being configured to direct a fluid toward a surface of the substrate positioned in contact with the first support roller;
a sensor disposed in the body, the sensor configured to direct an optical signal along the major axis of the channel and out of the outlet toward the substrate positioned in contact with the first support roller; and
a inlet in fluid communication with the outlet.

2. The apparatus of claim 1, wherein the sensor is an optical sensor configured to send and receive light through the outlet of the channel.

3. The apparatus of claim 1 further comprising a target in line with the major axis of the channel.

4. The apparatus of claim 1, wherein the major axis of the channel is about parallel to a first axis of the first support roller.

5. The apparatus of claim 1, further comprising an idler roller configured to monitor a first radial orientation of the substrate, the detection assembly configured to direct the optical signal through a notch in the substrate positioned in contact with the first support roller and the idler roller.

6. The apparatus of claim 1, wherein the channel is configured to direct a liquid through the inlet to the outlet.

7. The apparatus of claim 1, wherein the detection assembly further comprises a window disposed between the sensor and the channel.

8. A system for cleaning a substrate in semiconductor manufacturing, the system comprising:
a tank;
a cylindrical roller disposed in the tank, the cylindrical roller having a first axis;
a first support roller having a second axis disposed in the tank, the first axis disposed about perpendicular to the second axis, the first support roller configured to support and rotate a substrate in contact with the first support roller;
a detection assembly disposed in the tank, the detection assembly comprising:
a body;
a channel disposed through the body, the channel comprising an outlet;
a sensor disposed in the body, the sensor configured to direct an optical signal out of the outlet; and
an inlet in fluid communication with the outlet through the channel.

9. The system of claim 8, wherein the sensor comprises a fiber optic cable communicatively coupled to a controller, the controller configured to send and receive optical signals along the fiber optic cable.

10. The system of claim 8, further comprising a target disposed in the tank, the outlet of the channel directed towards the target.

11. The system of claim 8, wherein the tank comprises:
an upper ledge; and
a floor opposite the upper ledge, the detection assembly disposed closer to the floor than the upper ledge.

12. The system of claim 10, wherein the tank further comprises a window disposed in the body of the detection assembly, the sensor configured to direct the optical signal through the window and through the channel.

13. The system of claim 8, wherein the outlet is disposed less than 10 millimeters from the substrate when the substrate is disposed in the tank.

14. A system for cleaning a substrate in semiconductor manufacturing, the system comprising:
a tank;
a drain disposed in a wall or a floor of the tank;
a first support roller disposed in the tank and configured to support and rotate a substrate;
a detection assembly disposed in the tank, the detection assembly comprising:
a body;
a channel disposed through the body, the channel comprising an outlet;
a sensor disposed in the body, the sensor configured to direct an optical signal through the channel and out of the outlet; and
an inlet fluidly coupled to the outlet through the channel;
a controller communicatively coupled to the detection assembly, the controller comprising memory, the memory comprising instructions that, when executed by one or more processors, cause one or more operations to be conducted, the one or more operations comprising at least one of:
determining whether a substrate is present in the tank;
determining an orientation of the substrate in the tank; and
determining whether the drain is in a clogged state.

15. The system of claim 14, wherein determining the orientation of the substrate comprises:
rotating the substrate with the first support roller;
directing an optical signal through a liquid column;
detecting an intensity of a reflected signal; and
detecting a change in an intensity of the reflected signal, the change corresponding to a radial orientation of a notch on the substrate.

16. The system of claim 15, further comprising:
monitoring a time between a first change in intensity and a second change in intensity;
determining a radial orientation of the substrate after a full rotation and corresponding to the time monitored; and
comparing the radial orientation of the first support roller with a calculated orientation of the substrate.

17. The system of claim 14, wherein determining whether the substrate is present in the tank comprises:
rotating the first support roller;
flowing a liquid through the channel to form a liquid column through the outlet;
directing an optical signal from the sensor through the liquid column; and
determining a presence of a reflected signal with the sensor.

18. The system of claim 17, wherein determining the presence of the reflected signal further comprises:
determining whether the first support roller has rotated enough to un-align the optical signal with a notch of the substrate; and
transmitting the reflected signal from the sensor to the controller when the optical signal reflects from the substrate; and
determining the substrate is not present when the sensor does not detect the reflected signal.

19. The system of claim 14, wherein determining whether the drain is in a clogged state comprises:
directing an optical signal from the sensor toward a target disposed within the tank;
detecting, with the sensor, a presence of a first reflected signal having a first intensity;
rotating the first support roller;
detecting, with the sensor, a presence of a second reflected signal having a second intensity; and
determining a drain is in a clogged state if the first reflected signal and the second reflected signal are present.

20. The system of claim 19, further comprising:
determining the drain is in a clogged state when the first intensity and the second intensity are within a threshold of each other; and
determining the drain is not in a clogged state if only one of the first reflected signal and the second reflected signal are present.
